(19) United States
(12) Patent Application Publication
(10) Pub. No.: US 2020/0002840 A1
(43) Pub. Date: Jan. 2, 2020

(54) SYSTEMS FOR PRODUCING A MONOCRYSTALLINE INGOT THAT INVOLVE MONITORING NECK GROWTH MOVING AVERAGE

(71) Applicant: Global Wafers Co., Ltd., Hsinchu (TW)

(72) Inventors: Zheng Lu, O'Fallon, MO (US); Chun-Sheng Wu, Hsinchu City (TW); Feng-Chien Tsai, Taipei (TW); Chi-Yung Chen, New Taipei City (TW); Yeong-Ming Sheu, Hsinchu County (TW); Hsien-Ta Tseng, Toufen City (TW)

(21) Appl. No.: 16/021,962

(22) Filed: Jun. 28, 2018

(51) Int. Cl. C30B 15/26; C01B 33/02; C30B 15/14; C30B 29/06

(52) U.S. Cl. CPC C30B 15/26; C30B 29/06; C30B 15/14; C01B 33/02

(57) ABSTRACT

Methods for producing monocrystalline silicon ingots in which the pull rate during neck growth is monitored are disclosed. A moving average of the pull rate may be calculated and compared to a target moving average to determine if dislocations were not eliminated and the neck is not suitable for producing an ingot main body suspended from the neck.

### FIELD OF THE DISCLOSURE

The field of the disclosure relates to methods for producing monocrystalline silicon ingots in which the pull rate during neck growth is monitored. In some embodiments, a moving average of the pull rate is calculated and compared to a target moving average to determine if dislocations were not eliminated and the neck is not suitable for producing the silicon ingot main body.

### BACKGROUND

Single crystal silicon, which is the starting material for most processes for the fabrication of semiconductor electronic components, is commonly prepared by the Czochralski (“Cz”) method. In this method, polycrystalline silicon (“polysilicon”) is charged to a crucible and melted, a seed crystal is brought into contact with the molten silicon and a single crystal is grown by slow extraction. As crystal growth is initiated, dislocations are generated in the crystal from the thermal shock of contacting the seed crystal with the melt. These dislocations are propagated throughout the growing crystal and multiplied unless they are eliminated in a neck region between the seed crystal and the main body of the crystal.

Conventional methods for eliminating dislocations within a silicon single crystal include the so-called “dash neck method” which involves growing a neck having a small diameter (e.g., 2 to 4 mm) at a high crystal pull rate (e.g., as high as 6 mm/min) to completely eliminate dislocations before initiating growth of the main body of crystal. Generally, dislocations can be eliminated in these small diameter necks after approximately 100 to about 125 mm of the neck has been grown. Once the dislocations have been eliminated, the diameter of the crystal is enlarged to form a “cone” or “taper” portion. When the desired diameter of the crystal is reached, the cylindrical main body is then grown to have an approximately constant diameter.

While conventional methods for eliminating dislocations are mostly successful, such methods may result in some necks which include dislocations which propagate into the constant diameter portion of the ingot. Such ingots are not suitable for device fabrication and are scrapped at high cost.

A need exists for methods for preparing silicon ingots in which necks in which dislocations have not been eliminated may be detected to allow for growth of a second neck which is free of dislocations.

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

One aspect of the present disclosure is directed to a method for producing a monocrystalline silicon ingot having a neck and a main body suspended from the neck. A seed crystal is contacted with a silicon melt held within a crucible. A neck is pulled from the silicon melt. A pull rate at which the neck is pulled from the silicon melt is measured. A moving average from the measured pull rate is calculated. The moving average of the measured pull rate is compared to a target range. An ingot main body is pulled from the melt if the moving average is within the target range with the main body being suspended from the neck.

Another aspect of the present disclosure is directed to a method for controlling the quality of a neck used to support an ingot main body, the neck being pulled from a silicon melt. A pull rate at which the neck is pulled from the silicon melt is measured. A moving average of the pull rate is calculated from the measured pull rate. The moving average of the measured pull rate is compared to a target range. A signal is sent to terminate neck growth if the moving average falls outside of the target range.

Yet a further aspect of the present disclosure is directed to a system for producing a monocrystalline silicon ingot. The system includes a crystal puller in which the silicon ingot is pulled. The system includes a crucible for holding a polycrystalline silicon melt within the crystal puller. A seed crystal chuck secures a seed for contacting the silicon melt. The system includes a control unit for controlling growth of a neck from which an ingot main body is suspended. The control unit regulates the pull rate of the neck. The control unit is configured to calculate a moving average of the pull rate and compare the moving average to a target moving average. The control unit terminates the neck when the pull rate is outside of the target moving average.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1 is a schematic side view of a pulling apparatus for forming a single crystal silicon ingot;

FIG. 2 is a partial front view of a single crystal silicon ingot grown by the Czochralski method;

FIG. 3 is a cross-section of a crystal puller apparatus used to pull a single crystal silicon ingot from a silicon melt;

FIG. 4 is a block diagram of an example control system for regulating neck growth based on the moving average of the neck pull rate;

FIG. 5 is a block diagram of an example server system;

FIG. 6 is a block diagram of an example computing device;

FIG. 7 is a graph of the actual and 3 minute moving average of the neck pull rate during growth of a single crystal silicon ingot;

FIG. 8 is a graph of the 0.5 minute moving average, 1 minute moving average and 2 minute moving average of the actual neck growth pull rate of FIG. 7;

FIG. 9 is a graph of the 2 minute moving average, 3 minute moving average and 5 minute moving average of the actual neck growth pull rate of FIG. 7;

FIG. 10 is a graph of the actual neck pull rates for necks with dislocations and for dislocation-free necks;

FIG. 11 is a graph of the 2 minute moving average of the neck pull rates for necks with dislocations and for dislocation-free necks;

FIG. 12 is a graph of the 5 minute moving average of the neck pull rates for necks with dislocations and for dislocation-free necks; and

FIG. 13 is a graph of the 10 minute moving average of the neck pull rates for necks in which dislocations were not eliminated and for dislocation-free necks.

Corresponding reference characters indicate corresponding parts throughout the drawings.

### DETAILED DESCRIPTION

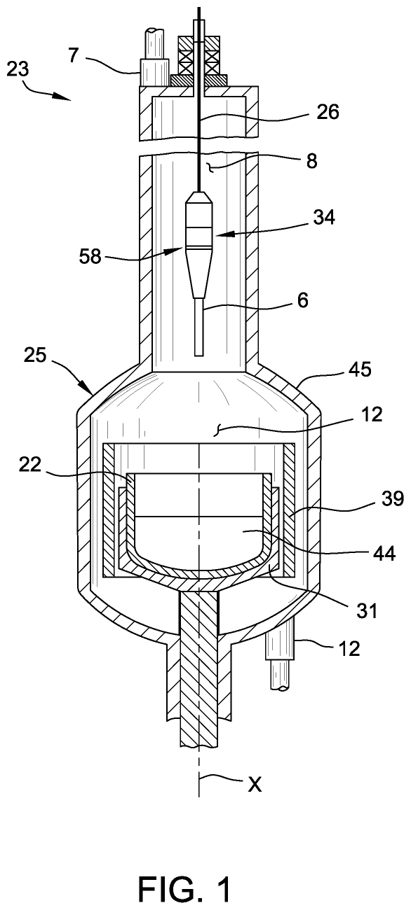

Provisions of the present disclosure relate to methods for producing a monocrystalline silicon ingot in which the quality of the neck portion of the ingot is monitored to determine if the neck is suitable for ingot growth or if the neck should be terminated (e.g., returned to the melt to be melted down or removed from the puller). In accordance with embodiments of the present disclosure and with reference to FIG. 1, the ingot is grown by the so-called Czochralski process in which the ingot is withdrawn from a silicon melt 44 held within a crucible 22 of an ingot puller 23.

The ingot puller 23 includes a housing 25 that defines a crystal growth chamber 12 and a pull chamber 8 having a smaller transverse dimension than the growth chamber 12. The growth chamber 12 has a generally dome shaped upper wall 45 transitioning from the growth chamber 12 to the narrowed pull chamber 8. The ingot puller 23 includes an inlet port 7 and an outlet port 11 which may be used to introduce and remove a process gas to and from the housing 25 during crystal growth.

The crucible 22 within the ingot puller 23 contains the polycrystalline silicon melt 44 from which a silicon ingot is drawn. The silicon melt 44 is obtained by melting polycrystalline silicon charged to the crucible 22. The crucible 22 is mounted on a turntable 31 for rotation of the crucible about a central longitudinal axis X of the ingot puller 23.

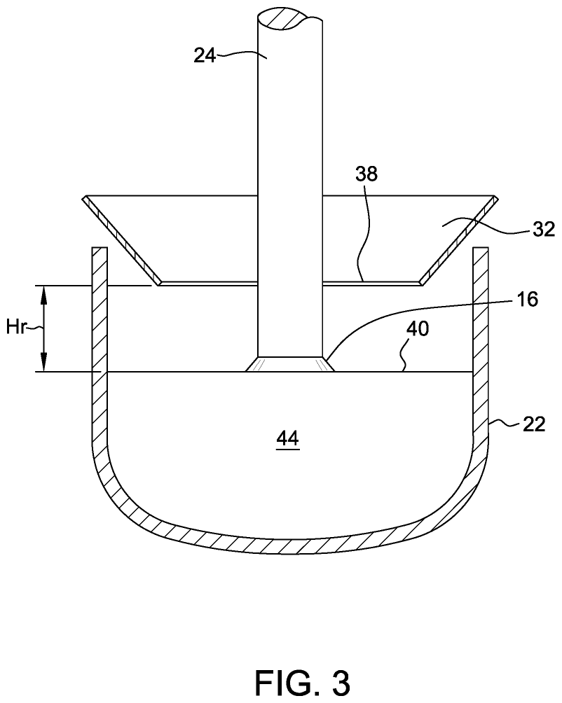

A heating system 39 (e.g., an electrical resistance heater) surrounds the crucible 22 for melting the silicon charge to produce the melt 44. The heater 39 may also extend below the crucible as shown in U.S. Pat. No. 8,317,919. The heater 39 is controlled by a control system (not shown) so that the temperature of the melt 44 is precisely controlled throughout the pulling process. Insulation (not shown) surrounding the heater 39 may reduce the amount of heat lost through the housing 25. The ingot puller 23 may also include a reflector assembly 32 (FIG. 3) above the melt surface 40 for shielding the ingot from the heat of the crucible 22 to increase the axial temperature gradient at the solid-melt interface.

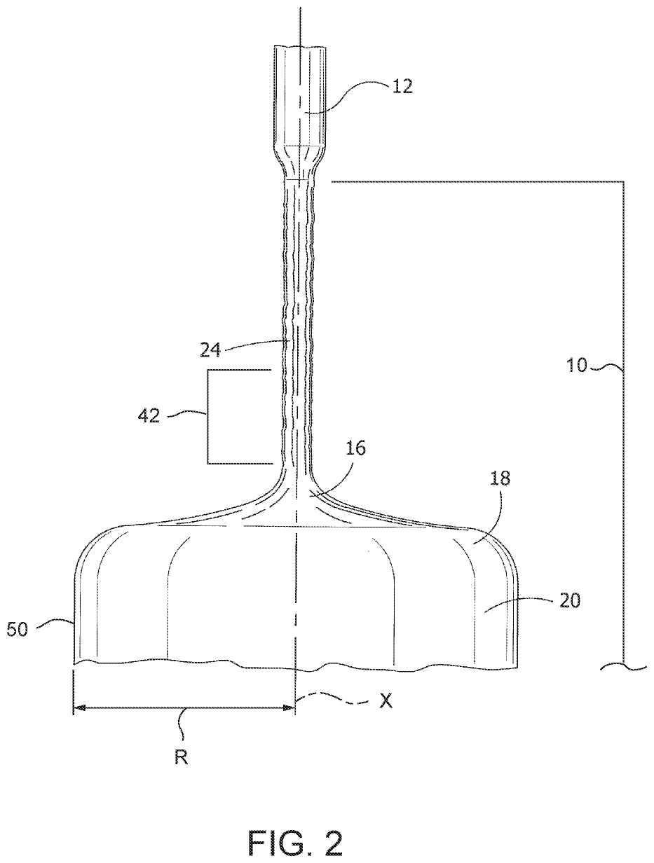

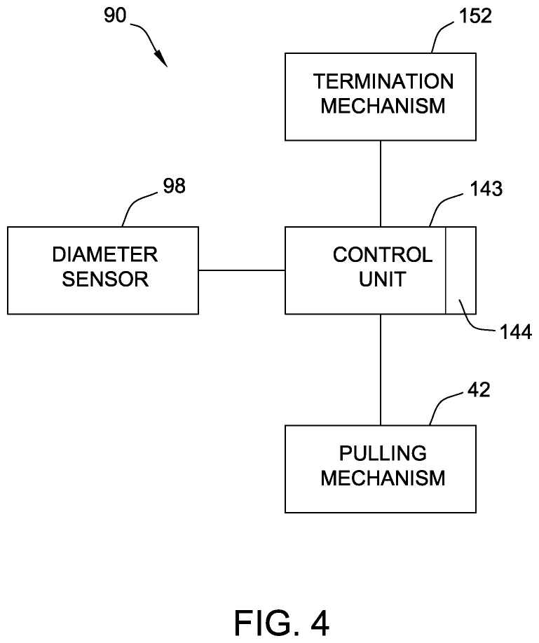

A pulling mechanism 42 (FIG. 4) is attached to a pull wire 26 (FIG. 1) that extends down from the mechanism. The pulling mechanism 42 is capable of raising and lowering the pull wire 26. The ingot puller 23 may have a pull shaft rather than a wire, depending upon the type of puller. The pull wire 26 terminates in a pulling assembly 58 that includes a seed crystal chuck 34 which holds a seed crystal 6 used to grow the silicon ingot. In growing the ingot, the pulling mechanism lowers the seed crystal 6 until it contacts the surface of the silicon melt 44. Once the seed crystal 6 begins to melt, the pulling mechanism 42 slowly raises the seed crystal 6 up through the growth chamber 12 and pull chamber 8 to grow the monocrystalline ingot. The speed at which the pulling mechanism 42 (FIG. 2) rotates the seed crystal 6 and the speed at which the pulling mechanism 42 raises the seed crystal 6 are controlled by the control unit 143.

A process gas is introduced through the inlet port 7 into the housing 25 and is withdrawn from the outlet port 11. The process gas creates an atmosphere within the housing and the melt and atmosphere form a melt-gas interface. The outlet port 11 is in fluid communication with an exhaust system (not shown) of the ingot puller.

A single crystal silicon ingot 10 produced in accordance with embodiments of the present disclosure and, generally, the Czochralski method is shown in FIG. 2. The ingot 10 includes a neck 24, an outwardly flaring portion 16 (synonymously “cone”), a shoulder 18 and a constant diameter main body 20. The neck 24 is attached to the seed crystal 6 that was contacted with the melt and withdrawn to form the ingot 10. The neck 24 terminates once the cone portion 16 of the ingot begins to form.

The constant diameter portion of the main body 20 has a circumferential edge 50, a central axis X that is parallel to the circumferential edge and a radius R that extends from the central axis to the circumferential edge. The central axis X also passes through the cone portion 16 and neck 24. The diameter of the main ingot body 20 may vary and, in some embodiments, the diameter may be about 150 mm, about 200 mm, about 300 mm, greater than about 300 mm, about 450 mm or even greater than about 450 mm.

The single crystal silicon ingot 10 may generally have any resistivity. In some embodiments, the resistivity of the ingot 10 may be less than about 20 mohm-cm, less than about 10 mohm-cm, or less than about 1 mohm-cm (e.g., 0.01 mohm-cm to about 20 mohm-cm or 0.1 mohm-cm to about 20 mohm-cm).

The single crystal silicon ingot 10 may be doped. In some embodiments, the ingot is nitrogen doped at a concentration of nitrogen of at least about 1×10¹³/cm³ (e.g., from about 1×10¹³/cm³ to about 1×10¹⁵/cm³). The resistivity and doping ranges described above are exemplary and should not be considered in a limiting sense unless stated otherwise.

Generally, the melt from which the ingot is drawn is formed by loading polycrystalline silicon into the crucible 22 (FIG. 1) to form a silicon charge. A variety of sources of polycrystalline silicon may be used including, for example, granular polycrystalline silicon produced by thermal decomposition of silane or a halosilane in a fluidized bed reactor or polycrystalline silicon produced in a Siemens reactor. Once polycrystalline silicon is added to the crucible to form a charge, the charge is heated to a temperature above about the melting temperature of silicon (e.g., about 1412° C.) to melt the charge. In some embodiments, the charge (i.e., the resulting melt) is heated by the heating system 39 to a temperature of at least about 1425° C., at least about 1450° C. or even at least about 1500° C. Once the charge is liquefied to form a silicon melt, the silicon seed crystal 6 is lowered to contact the melt. The crystal 6 is then withdrawn from the melt with silicon being attached thereto (i.e., with a neck 24 being formed) thereby forming a melt-solid interface near or at the surface of the melt. After formation of the neck, the outwardly flaring cone portion 16 adjacent the neck 24 is grown. The main ingot body 20 having a constant diameter adjacent the cone portion 16 is then grown.

In some embodiments, heat transfer at the melt-solid interface during growth of the main body 20 is controlled by a device such as a reflector, a radiation shield, a heat shield, an insulating ring, a purge tube or any other similar device capable of manipulating a temperature gradient known generally to one skilled in the art. Heat transfer may also be controlled by adjusting the power supplied to heaters below or adjacent to the crystal melt or by controlling the crucible rotation or magnetic flux in the melt. In a preferred embodiment, heat transfer at the melt-solid interface is controlled using a reflector in proximity to the melt surface as shown in FIG. 3. It should be noted that while the methods of the present disclosure described below are generally described with reference to such a reflector, the methods of the present disclosure are also applicable to the other heat transfer control devices listed above and reference herein to use of a reflector should not be considered in a limiting sense. During formation of the neck 24, heat transfer is typically controlled by use of a device such as the reflector or other device such as a radiation shield, heat shield, insulating ring or purge tube.

Referring now to FIG. 3, a portion of a crystal pulling apparatus is shown. As shown in FIG. 3, an ingot neck 24 has been pulled from the melt surface 40 and the cone portion 16 of the ingot is beginning to form. The apparatus includes a crucible 22 and a reflector assembly 32 (synonymously “reflector”). As is known in the art, the hot zone apparatus, such as the reflector assembly 32, is often disposed within the crucible 22 for thermal and/or gas flow management purposes. For example, the reflector 32 is, in general, a heat shield adapted to retain heat underneath itself and above the melt 44. In this regard, any reflector design and material of construction (e.g., graphite or gray quartz) known in the art may be used without limitation. As shown in FIG. 3, the reflector assembly 32 has an inner surface 38 that defines a central opening through which the ingot is pulled from the crystal melt 44.

In accordance with embodiments of the present disclosure, as the neck 24 is pulled from the silicon melt 44, the pull rate at which the neck is pulled from the melt 44 is measured. A moving average from the measured pull rate is calculated and the moving average is compared to a target range of the moving average. If the moving average is within the target range, growth continues and the constant diameter portion 20 or “main body” of the ingot is formed with the neck 24 supporting the main body 24 (i.e., a main body connected to the neck is formed). If the moving average is not within the target range, the main body is not formed in the pull cycle. The neck is returned to the melt or removed from the puller and a second neck is formed for growth of the ingot main body. The second neck may also be analyzed to determine if its growth rate falls within the target range.

The neck pull rate may be measured directly or may be a pull rate that is measured by a control unit (e.g., measured from output signals), such as a pull rate that is calculated to provide a desired neck diameter. The control unit may be integrated with one or more sensors that cooperate to regulate the neck pull rate (e.g., sensors integrated with the pulling mechanism 42 and/or ingot diameter sensors). In some embodiments, the heating system power is kept relatively constant while measuring the neck pull rate. For example, the output power of the heating system may be maintained within about +/−0.5 kW of an average or target power or even about +/−0.25 kW of the average or target power.

An example control system 90 is shown in FIG. 4. The diameter of the neck may be sensed by diameter sensor 98. Example diameter sensors 98 include cameras, pyrometers, photo diodes, PMT (photomultiplier tube), and the like. The sensor 98 relays a signal related to the dimeter of the neck to a control unit 143. The control unit 143 regulates the diameter of the neck by sending a signal to a pulling mechanism 53 so as to increase or decrease the pull rate, thereby causing the diameter of the neck to increase or decrease. As the neck is grown, the pull rate as determined by the control unit 143 varies.

In some embodiments, the moving average of the neck pull rate is averaged over the time at which the neck is pulled (e.g., the pull rate is measured at intervals of time and a moving average over a period of time is calculated). In some embodiments, a time-averaged neck pull rate is calculated with the average being an average over at least about the previous 5 seconds, or at least about the previous 30 seconds, at least about the previous minute, at least about the previous 2 minutes, at least about the previous 5 minutes or at least about the previous 10 minutes (e.g., about the previous 5 seconds to about the previous 25 minutes, about the previous 30 seconds to about the previous 20 minutes, or about the previous 2 minutes to about the previous 10 minutes).

In other embodiments, the moving average of the neck pull rate is averaged over the length of the neck (e.g., the pull rate is measured at intervals of length of the neck and a moving average over a length of neck is calculated). In some embodiments, the length-averaged neck pull rate is calculated with the average being an average over at least about the previous 0.2 mm, at least about the previous 1 mm, at least about the previous 2 mm, at least about the previous 4 mm, at least about the previous 10 mm or at least about the previous 20 mm (e.g., from about the previous 0.2 mm to about the previous 50 mm, or about the previous 4 mm to about the previous 20 mm).

As the moving average is calculated, the calculated moving average is compared to a target moving average. The control unit may be the same control unit 143 (FIG. 4) used to regulate the neck diameter and/or calculate the moving average or may be a different control unit.

The control unit 143 may include a processor 144 that processes the signals received from various sensors of the crystal puller 23, including, but not limited to, the diameter sensor 98. The control unit 143 may also be in communication with other sensors or devices including the heating system 39 (FIG. 1), gas flow controller (e.g., an argon flow controller), melt surface temperature sensor, and any combination thereof.

Control unit 143 may be a computer system. Computer systems, as described herein, refer to any known computing device and computer system. As described herein, all such computer systems include a processor and a memory. However, any processor in a computer system referred to herein may also refer to one or more processors wherein the processor may be in one computing device or a plurality of computing devices acting in parallel. Additionally, any memory in a computer device referred to herein may also refer to one or more memories wherein the memories may be in one computing device or a plurality of computing devices acting in parallel.

The term processor, as used herein, refers to central processing units, microprocessors, microcontrollers, reduced instruction set circuits (RISC), application specific integrated circuits (ASIC), logic circuits, and any other circuit or processor capable of executing the functions described herein. The above are examples only, and are thus not intended to limit in any way the definition and/or meaning of the term “processor.”

As used herein, the term “database” may refer to either a body of data, a relational database management system (RDBMS), or to both. As used herein, a database may include any collection of data including hierarchical databases, relational databases, flat file databases, object-relational databases, object oriented databases, and any other structured collection of records or data that is stored in a computer system. The above examples are example only, and thus are not intended to limit in any way the definition and/or meaning of the term database. Examples of RDBMS's include, but are not limited to including, Oracle® Database, MySQL, IBM® DB2, Microsoft® SQL Server, Sybase®, and PostgreSQL. However, any database may be used that enables the systems and methods described herein. (Oracle is a registered trademark of Oracle Corporation, Redwood Shores, Calif.; IBM is a registered trademark of International Business Machines Corporation, Armonk, N.Y.; Microsoft is a registered trademark of Microsoft Corporation, Redmond, Wash.; and Sybase is a registered trademark of Sybase, Dublin, Calif.)

In one embodiment, a computer program is provided to enable control unit 143, and this program is embodied on a computer readable medium. In an example embodiment, the computer system is executed on a single computer system, without requiring a connection to a server computer. In a further embodiment, the computer system is run in a Windows® environment (Windows is a registered trademark of Microsoft Corporation, Redmond, Wash.). In yet another embodiment, the computer system is run on a mainframe environment and a UNIX® server environment (UNIX is a registered trademark of X/Open Company Limited located in Reading, Berkshire, United Kingdom). Alternatively, the computer system is run in any suitable operating system environment. The computer program is flexible and designed to run in various different environments without compromising any major functionality. In some embodiments, the computer system includes multiple components distributed among a plurality of computing devices. One or more components may be in the form of computer-executable instructions embodied in a computer-readable medium.

The computer systems and processes are not limited to the specific embodiments described herein. In addition, components of each computer system and each process can be practiced independent and separate from other components and processes described herein. Each component and process also can be used in combination with other assembly packages and processes.

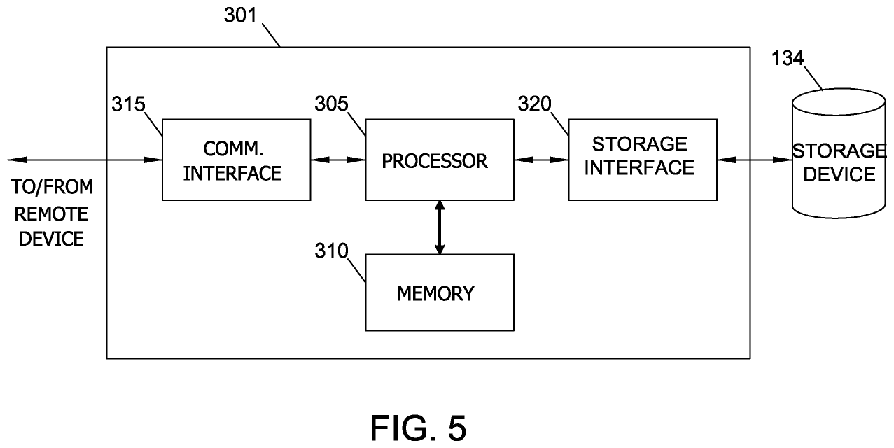

In one embodiment, the computer system may be configured as a server system. FIG. 5 illustrates an example configuration of a server system 301 used to receive measurements from one or more sensors including, but not limited to, the diameter sensor 98, as well as to control one or more devices of the crystal puller 23 including, but not limited to the pulling mechanism 42 and neck termination mechanism 152. Referring again to FIG. 4, server system 301 may also include, but is not limited to, a database server. In this example embodiment, server system 301 performs all of the steps used to control one or more devices of system 90 as described herein.

Server system 301 includes a processor 305 for executing instructions. Instructions may be stored in a memory area 310, for example. Processor 305 may include one or more processing units (e.g., in a multi-core configuration) for executing instructions. The instructions may be executed within a variety of different operating systems on the server system 301, such as UNIX, LINUX, Microsoft Windows®, etc. It should also be appreciated that upon initiation of a computer-based method, various instructions may be executed during initialization. Some operations may be required in order to perform one or more processes described herein, while other operations may be more general and/or specific to a particular programming language (e.g., C, C#, C++, Java, or any other suitable programming languages).

Processor 305 is operatively coupled to a communication interface 315 such that server system 301 is capable of communicating with a remote device such as a user system or another server system 301. For example, communication interface 315 may receive requests (e.g., requests to provide an interactive user interface to receive sensor inputs and to control one or more devices of the crystal puller 23 from a client system via the Internet).

Processor 305 may also be operatively coupled to a storage device 134. Storage device 134 is any computer-operated hardware suitable for storing and/or retrieving data. In some embodiments, storage device 134 is integrated in server system 301. For example, server system 301 may include one or more hard disk drives as storage device 134. In other embodiments, storage device 134 is external to server system 301 and may be accessed by a plurality of server systems 301. For example, storage device 134 may include multiple storage units such as hard disks or solid state disks in a redundant array of inexpensive disks (RAID) configuration. Storage device 134 may include a storage area network (SAN) and/or a network attached storage (NAS) system.

In some embodiments, processor 305 is operatively coupled to storage device 134 via a storage interface 320. Storage interface 320 is any component capable of providing processor 305 with access to storage device 134. Storage interface 320 may include, for example, an Advanced Technology Attachment (ATA) adapter, a Serial ATA (SATA) adapter, a Small Computer System Interface (SCSI) adapter, a RAID controller, a SAN adapter, a network adapter, and/or any component providing processor 305 with access to storage device 134.

Memory area 310 may include, but is not limited to, random access memory (RAM) such as dynamic RAM (DRAM) or static RAM (SRAM), read-only memory (ROM), erasable programmable read-only memory (EPROM), electrically erasable programmable read-only memory (EEPROM), and non-volatile RAM (NVRAM). The above memory types are exemplary only, and are thus not limiting as to the types of memory usable for storage of a computer program.

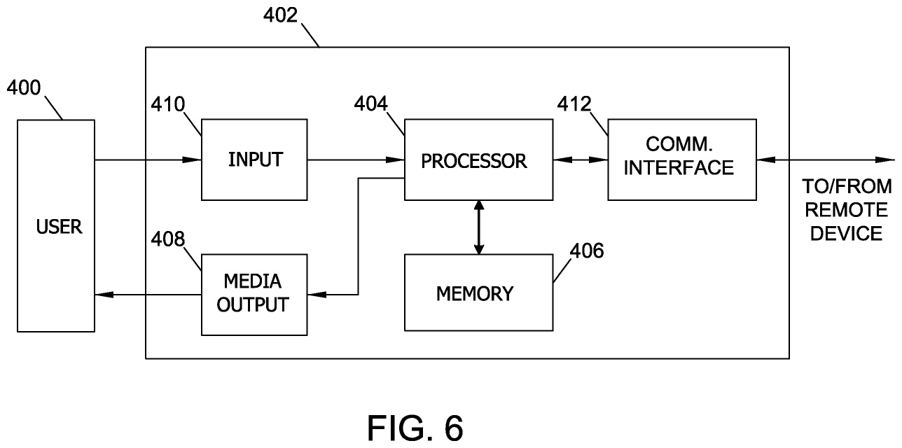

In another embodiment, the computer system may be provided in the form of a computing device, such as a computing device 402 (shown in FIG. 6). Computing device 402 includes a processor 404 for executing instructions. In some embodiments, executable instructions are stored in a memory area 406. Processor 404 may include one or more processing units (e.g., in a multi-core configuration). Memory area 406 is any device allowing information such as executable instructions and/or other data to be stored and retrieved. Memory area 406 may include one or more computer-readable media.

In another embodiment, the memory included in the computing device of the control unit 143 may include a plurality of modules. Each module may include instructions configured to execute using at least one processor. The instructions contained in the plurality of modules may implement at least part of the method for simultaneously regulating a plurality of process parameters as described herein when executed by the one or more processors of the computing device. Non-limiting examples of modules stored in the memory of the computing device include: a first module to receive measurements from one or more sensors and a second module to control one or more devices of the system 90.

Computing device 402 also includes one media output component 408 for presenting information to a user 400. Media output component 408 is any component capable of conveying information to user 400. In some embodiments, media output component 408 includes an output adapter such as a video adapter and/or an audio adapter. An output adapter is operatively coupled to processor 404 and is further configured to be operatively coupled to an output device such as a display device (e.g., a liquid crystal display (LCD), organic light emitting diode (OLED) display, cathode ray tube (CRT), or “electronic ink” display) or an audio output device (e.g., a speaker or headphones).

In some embodiments, client computing device 402 includes an input device 410 for receiving input from user 400. Input device 410 may include, for example, a keyboard, a pointing device, a mouse, a stylus, a touch sensitive panel (e.g., a touch pad or a touch screen), a camera, a gyroscope, an accelerometer, a position detector, and/or an audio input device. A single component such as a touch screen may function as both an output device of media output component 408 and input device 410.

Computing device 402 may also include a communication interface 412, which is configured to communicatively couple to a remote device such as server system 302 or a web server. Communication interface 412 may include, for example, a wired or wireless network adapter or a wireless data transceiver for use with a mobile phone network (e.g., Global System for Mobile communications (GSM), 3G, 4G or Bluetooth) or other mobile data network (e.g., Worldwide Interoperability for Microwave Access (WIMAX)).

Stored in memory 406 are, for example, computer-readable instructions for providing a user interface to user 400 via media output component 408 and, optionally, receiving and processing input from input device 410. A user interface may include, among other possibilities, a web browser and an application. Web browsers enable users 400 to display and interact with media and other information typically embedded on a web page or a website from a web server. An application allows users 400 to interact with a server application. The user interface, via one or both of a web browser and an application, facilitates display of information related to the process of producing a single crystal silicon ingot with low oxygen content.

The control unit 143 compares the calculated moving average to the target moving average. The target moving average may be stored in memory 310 (FIG. 5), database or look-up table. The target moving average may be input by a user by user input device 410 (FIG. 6).

The target moving average may vary depending on the particular crystal puller 23 (FIG. 1) and/or reflector assembly 32 (FIG. 3). Generally, the target moving average may be determined for the particular puller and/or reflector configuration by any method available to those of skill in the art. In some embodiments, the target moving average is determined by (1) growing a plurality of necks (and optionally ingot main bodies) while monitoring the moving average of the neck pull rate and (2) determining the moving average of the neck pull rates for necks that were not dislocation-free (i.e., zero dislocation) by the end of neck growth. The duration of the averaging may be determined in the same or similar manner. Zero dislocation of the neck may be determined by microscopy after a decorative etch or XRT (X-ray topography), or the like. In some embodiments, the target moving average of the neck pull rate is a maximum moving average (e.g., a moving average that, if exceeded, results in neck growth being terminated as explained further below). The target moving average may also include a minimum moving average (e.g., a moving average that, if the moving average moves below the target minimum moving average, neck growth is terminated).

In some embodiments (and depending on the crystal puller configuration), the target for the moving average of the crystal pull rate (e.g., at 2, 5 or 10 minute moving averages) is 3 mm/min or less, 4 mm/min or less, 4.5 mm/min or less (e.g., 1 mm/min to 4.5 mm/min or 1 mm/min to 4.0). It should be noted that the target moving averages of the neck pull rate are exemplary and other target moving averages may be used unless stated otherwise.

The moving average may be calculated and compared to the target moving average over the entire length of the neck or for only a portion of the neck (e.g., at least 25% of the length, at least 50% or at least 75% of the length). In various embodiments, the neck 24 has a length of at least 100 mm, at least 150 mm, or at least about 200 mm (e.g., from about 100 mm to about 400 mm, from about 100 mm to about 300 mm, or from about 150 mm to about 250 mm). In various embodiments, the constant diameter portion of the ingot may have a length from about 1500 mm to about 2500 mm or about 1700 mm to about 2100 mm.

In accordance with embodiments of the present disclosure, if the moving average falls outside of the target moving average (e.g., exceeds a maximum moving average), the control unit sends a signal to a termination mechanism 152 (FIG. 4). For example, the termination mechanism 152 may be a warning signal such as an alarm that alerts a technician that the moving average of the pull rate has fallen outside the target range of the pull rate and/or that the neck may include dislocations and should not be used for growth of the main body of the ingot. In such embodiments, the technician may cause the neck to be returned to the melt to melt the neck down and for growth of a second neck or the technician may cause the neck to form an end cone and may remove the neck from the ingot puller. In some embodiments, the termination mechanism 152 is the pulling mechanism 42. In such embodiments, the control unit 143 sends a signal to the pulling mechanism 42 to cause the pulling mechanism 42 to lower the neck into the melt to melt down the neck.

After the neck is terminated (e.g., returned to the melt for meltdown), a second neck may be grown. The crystal puller may undergo a stabilization period before growth of the second neck to allow the chuck and seed to be sufficiently preheated. The pull rate of the second neck may be measured. A moving average may be calculated from the measured pull rate and the moving average compared to the target range of the pull rate. A silicon ingot main body is grown from the second neck if the moving average of the measured pull rate is within the target range.

Compared to conventional methods for producing monocrystalline silicon ingots, the methods of embodiments of the present disclosure have several advantages. By calculating a moving average of the neck pull rate, changes in the pull rate profile that result from the diameter control loop and diameter fluctuation and measurement error may be reduced. This allows the profile to be monitored to determine if the moving average pull rate has fallen outside of a target range which indicates that the neck may include dislocations. Without being bound by any particular theory, it is believed that thermal shock between the seed and the melt may cause dislocations to be multiplied throughout the neck. Thermal shock-induced dislocations are believed to be difficult to eliminate with conventional methods (e.g., dash neck methods). Differences in temperature between the seed and melt may result from the melt temperature not being well stabilized, from the seed crystal not being sufficiently preheated (e.g., with a relatively large difference between temperatures of the crystal and neck causing the average neck growth rates to be relatively large), or the heater system power not being properly set. In instances in which the melt is relatively cool, the neck may solidify rapidly causing the pull rate to increase. In instances in which the melt is relatively hot, the neck solidifies slower causing the pull rate to be reduced. By taking the moving average of the pull rate and comparing the moving average to a target moving average, thermal shock between the seed and the melt may be detected. In such instances, the neck may be terminated (e.g., returned to the melt) and a second neck formed for formation of the ingot. The moving average of the pull rate of the second neck may also be determined and compared to the target moving average to determine if the second neck may include dislocations.

The methods may be particularly advantageous in environments in which the incidence at which dislocations are not eliminated from the neck is relatively high, such as relatively high diameter ingots (e.g., 200 mm or 300 mm or more), the ingot having a relatively low resistivity such as less than about 20 mohm-cm, and/or the ingot being nitrogen doped at a concentration of at least about 1×10¹³ atoms/cm³.

### EXAMPLES

The processes of the present disclosure are further illustrated by the following Examples. These Examples should not be viewed in a limiting sense.

### Example 1: Comparison of the Actual Neck Pull Rate Profile and the 3 Minute Moving Average

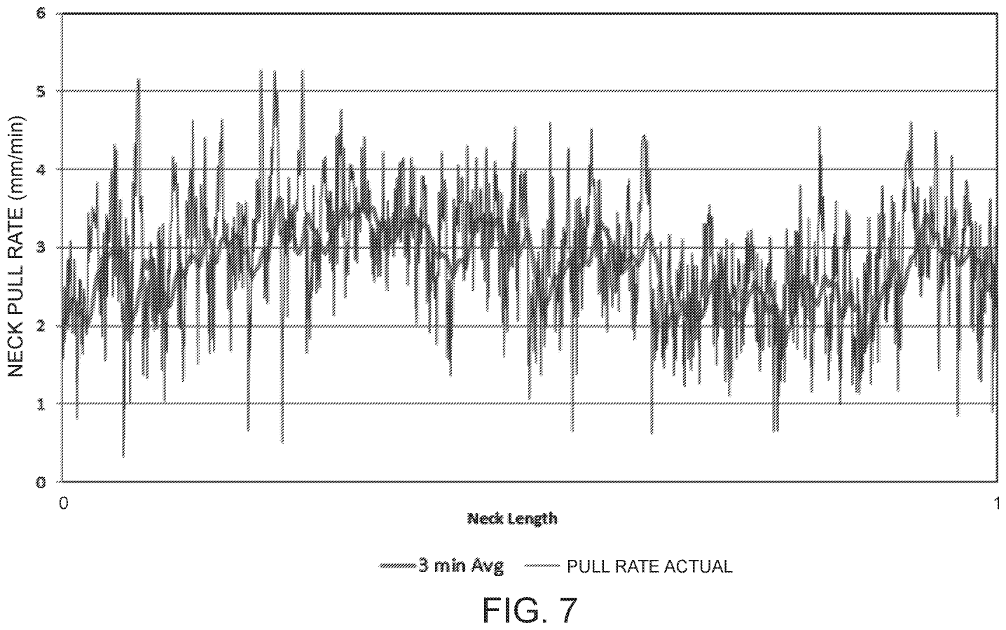

The actual pull rate over the length of the neck of a single crystal silicon ingot produced in an apparatus such as the apparatus of FIG. 1 is shown in FIG. 7. As may be seen from FIG. 7, the actual seed lift profile in a typical neck growth has many high frequency seed lift changes. The changes may functionally be part of the diameter control loop and some changes may be caused by diameter fluctuation and measurement error etc. The level of seed lift fluctuation does not detrimentally affect diameter control. However, the degree of fluctuations in the exemplary profile of FIG. 7 makes it difficult to correlate the profile with growth conditions.

The three minute moving average of the neck pull rate is also shown in FIG. 7. As shown in FIG. 7, the noise level is significantly reduced which enables development of longer term growth trends. The longer term growth trend may be correlated to melt stabilization (e.g., proper heater power) and the thermal shock between the seed and the neck.

### Example 2: Selection of the Duration Over Which the Pull Rate is Averaged

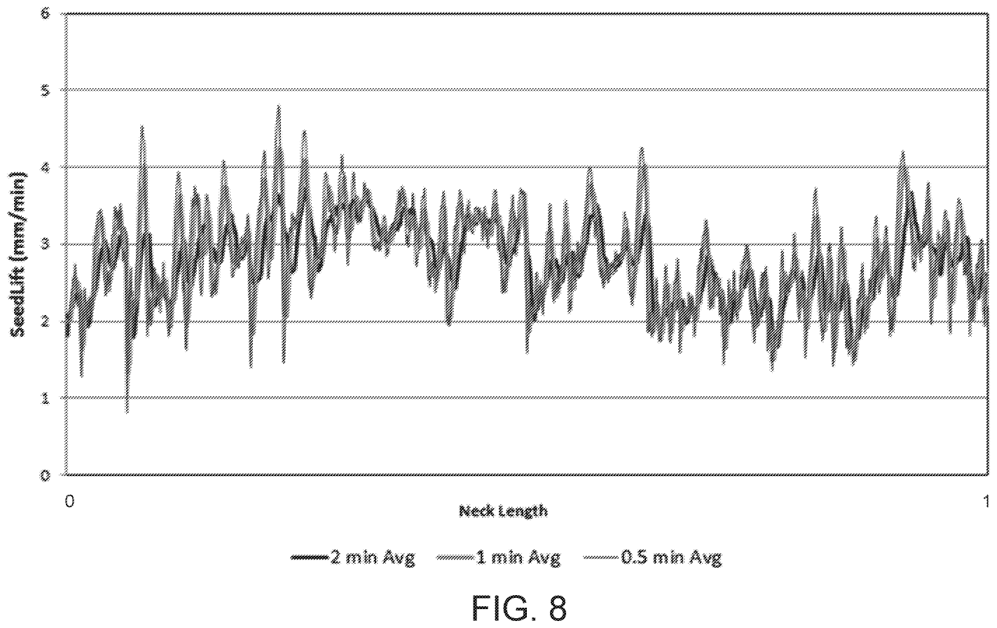

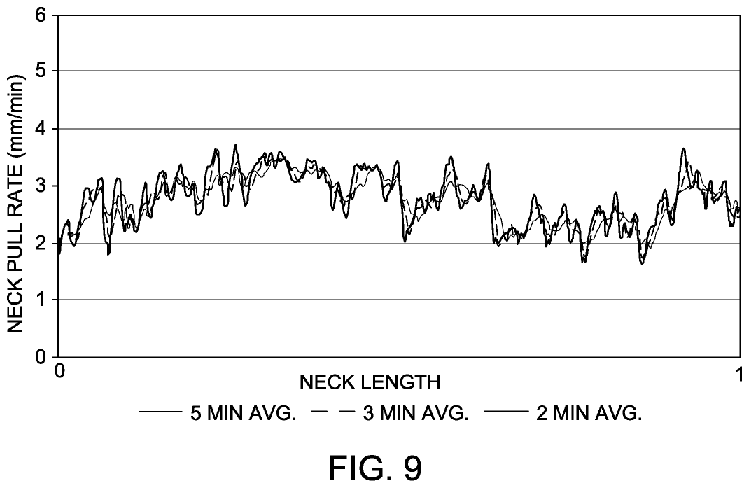

The 0.5 minute moving average, 1 minute moving average and 2 minute moving average of the actual neck pull rate of Example 1 are shown in FIG. 8 and the 2 minute moving average, 3 minute moving average and 5 minute moving average are shown in FIG. 9. As shown in FIGS. 8 and 9, the more high frequency fluctuation is reduced or eliminated by the averaging effect. An average duration is selected to remove short term signal and noise while enabling the quantification with sufficient sensitivity (e.g., zero dislocation achieved in the neck prior to growth of the constant diameter portion of the ingot). The duration over which the pull rate is averaged may depend on the hot zone configuration, melt flow profile and growth conditions.

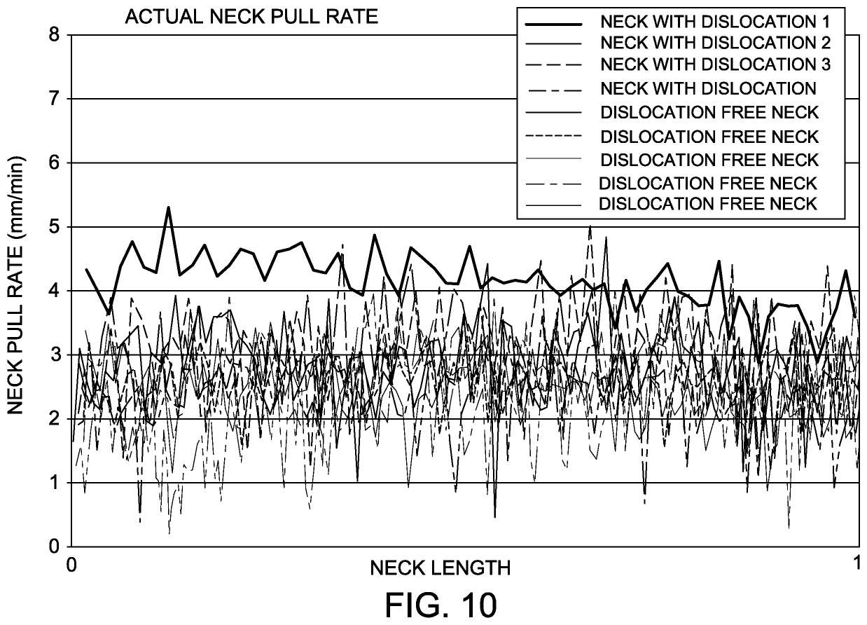

Selection of the duration over which the pull rate is averaged may be determined by comparing the moving averages of a number of durations for necks that did not achieve zero dislocation verse those that did achieve zero dislocation. As shown in FIG. 10, there may be noticeable differences in the actual neck pull rate profile between necks with dislocations and those in which dislocation have been eliminated (e.g., higher pull rates). However, the differences are difficult to quantify because the large fluctuations in pull rate causes the profiles to overlap at various locations throughout the entire neck growth.

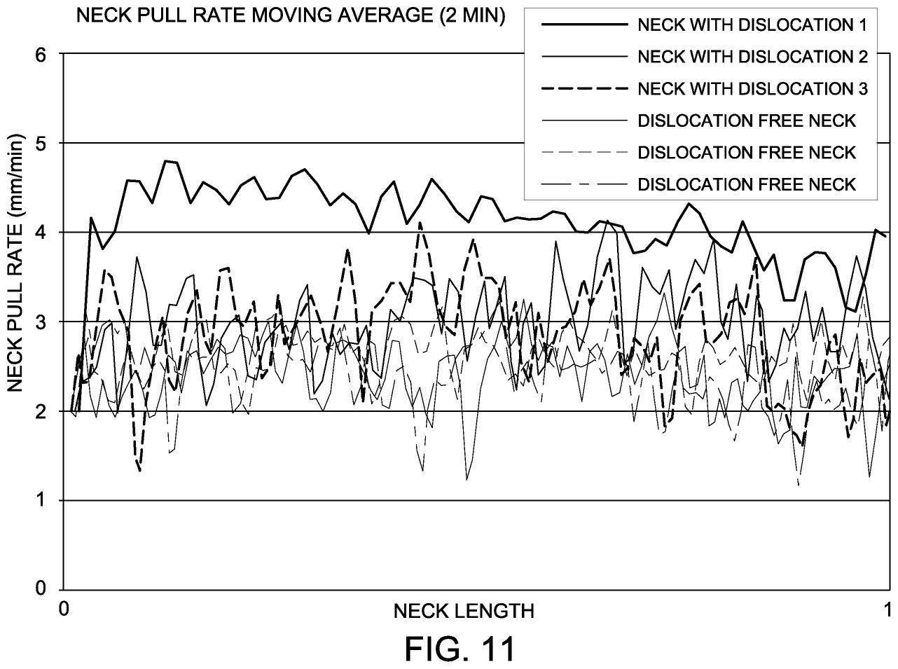

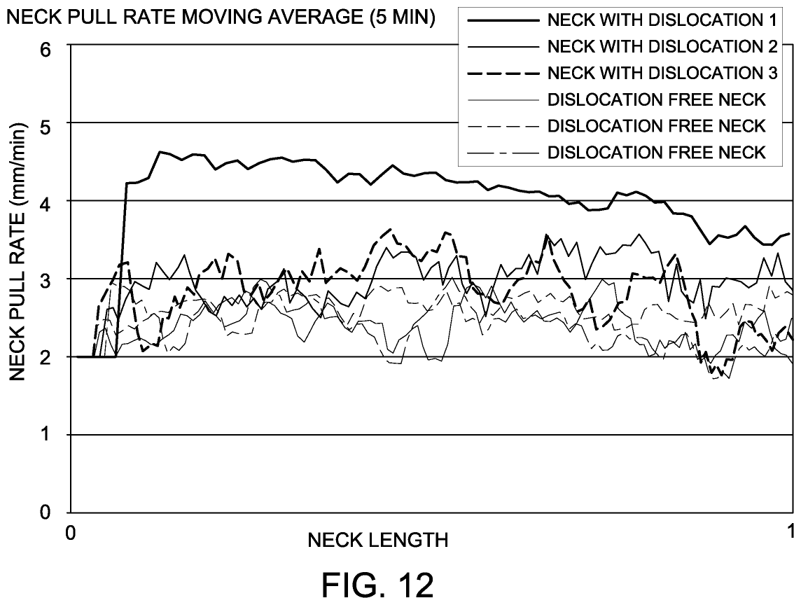

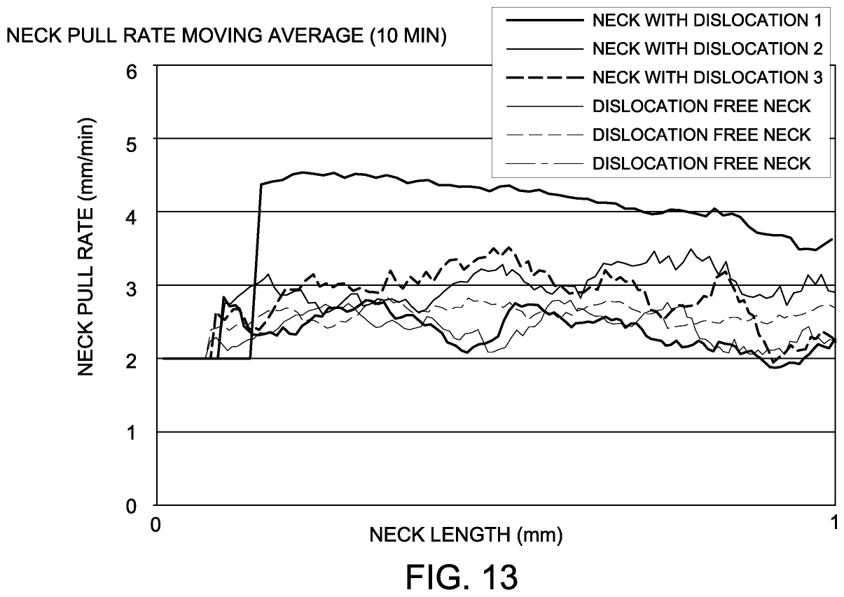

As shown in FIGS. 11-13 in which the 2 minute, 5 minute and 10 minute moving averages are shown, the differences between the lift profiles of the neck are easier to quantify for necks with dislocations compared to those in which dislocations are eliminated. In the particular hot-zone configuration of the crystal puller from which the necks were grown (e.g., 300 mm and relatively heavy doping), a moving average between 2 minutes and 5 minutes allows the differences between necks with dislocations and necks in which dislocations were eliminated to be quantified accurately in a wide spread of operating conditions. For example, if a target moving average of 3.3 mm/min is set over the entire length of the ingot for this particular crystal puller configuration such that necks having a moving average greater than 3.3 mm/min are returned to the melt, necks with dislocations may be reduced significantly (e.g., a reduction of 20 times or more), if not eliminated. More lightly doped applications using the same hot zone configuration may use an upper limit of 3.5 mm/min with significant reduction in necks with dislocations.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a”, “an”, “the” and “said” are intended to mean that there are one or more of the elements. The terms “comprising,” “including,” “containing” and “having” are intended to be inclusive and mean that there may be additional elements other than the listed elements. The use of terms indicating a particular orientation (e.g., “top”, “bottom”, “side”, etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

What is claimed is:

1. A system for producing a monocrystalline silicon ingot comprising:
a crystal puller in which the silicon ingot is pulled;
a crucible for holding a polycrystalline silicon melt within the crystal puller;
a seed crystal chuck that secures a seed for contacting the silicon melt; and
a control unit for controlling growth of a neck from which an ingot main body is suspended, the control unit regulating the pull rate of the neck, the control unit being configured to calculate a moving average of the pull rate and compare the moving average to a target moving average, the control unit terminating the neck when the pull rate is outside of the target moving average.

2. The system as set forth in claim 1 further comprising a termination mechanism for terminating neck growth, the termination mechanism being communicatively connected to the control unit.

3. The system as set forth in claim 2 wherein the termination mechanism produces a warning signal for alerting a technician.

4. The system as set forth in claim 2 wherein the warning signal causes an alarm to alert the technician.

5. The system as set forth in claim 1 wherein the control unit controls a heating system for heating the melt, the control unit being configured to maintain a power of the heating system within about +/−0.5 kW of an average power while calculating the moving average.

6. The system as set forth in claim 1 wherein the control unit controls a heating system for heating the melt, the control unit being configured to maintain a power of the heating system within about +/−0.25 kW of an average power while calculating the moving average.

7. The system as set forth in claim 1 comprising a sensor for measuring the neck pull rate.
